(19) United States
(12) Patent Application Publication
(10) Pub. No.: US 2003/0112483 A1
(43) Pub. Date: Jun. 19, 2003

(54) Image forming method

(76) Inventors: Hiroaki Takano, Tokyo (JP); Tsukasa Ito, Tokyo (JP)

Correspondence Address: CANTOR COLBURN LLP, 55 Griffin Road South, Boomfield, CT, 06002, US

(21) Appl. No.: 10/316,656

(22) Filed: Dec. 10, 2002

(30) Foreign Application Priority Data
Dec. 18, 2001 (JP) 384632/2001

(51) Int. Cl. G03F 3/08

(52) U.S. Cl. 358/521

(57) ABSTRACT

There is described a method for processing digital image data to be stored in a storage medium. The digital image data are created by applying a predetermined image-processing to original image data, which are read and converted from a visible pigment image through an image-inputting device after developing the visible pigment image on a silver-halide photosensitive material processed by an image-wise exposing operation. The method includes the steps of: designating an output-gradation number of the digital image data to be stored in the storage medium; retrieving a gradation-setting data set, corresponding to the output-gradation number designated in the designating step, from a plurality of gradation-setting data sets, each of which corresponds to each of a plurality of output-gradation numbers established in advance; and adjusting a gradation characteristic of the digital image data, based on the gradation-setting data set retrieved in the retrieving step.

### BACKGROUND OF THE INVENTION

The present invention relates to an image forming method by which the digital image data is obtained from a silver halide color photographic photosensitive material.

Recently a photographic system using the silver halide color photographic photosensitive material is further developed, and by the spread of a color laboratory which is a large scale concentric point at which a large amount of color prints are produced in the high efficiency, or by the spread of a so-called Mini-lab which is a small type and simple printer processor, it becomes a common situation that every one can easily enjoy the color photographing.

As a principle of the presently spreading color photography, the color reproduction by the subtractive color system is adopted. In the general color negative film, the photosensitive layer using a silver halide emulsion which is a photosensitive element in which the photosensitivity is added to a blue, green, and red area on the transmission substrate, is provided, and in these photosensitive layer, so-called color coupler for forming yellow, magenta and cyan color elements which are hues each of which is a complementary color, is combined and included.

A color negative film, which is image-wise exposed by the photographing, is developed in the color development liquid including the aromatic first class amine developing agent. In this case, the exposed silver halide particle is developed, that is, reduced by the developing agent, and each coloring matter is formed by the simultaneously generated oxidant of the developing agent and the coupling reaction of the color coupler. After that, the metallic silver generated by the development and non-reacted silver halide are respectively removed by the breaching and fixing processing, and the pigment image is obtained.

Onto the color print paper which is the color photosensitive material in which the photosensitive layer having a combination of the same photosensitive wavelength area and coloring hue is coated on the reflective supporting body, the optical exposure is given through the developed color negative film, and by processing the same coloring development, breaching and fixing, a color print formed of the pigment image onto which an original scene is reproduced, is obtained.

By the conventional analog method by which the optical exposure is given through the developed color negative film onto the color print paper, by adjusting the exposure time onto the print paper, and color balance of the exposing light, the color print with the adequate density and color reproduction is obtained. Although the adjustment of the exposure time and the color balance is automated by the high degree control technology, the photographic scene such as the rear-light, or strobe neighboring photographing, requires a manual operation by the operator. This is for the reason why, by the existence of the object having the high reflective factor or brightness rate, a deviation is generated in the color negative film coloring density in the photographic frame, and the average density in the photographic frame results in the situation that it does not express the lightness of the photographic scene around the main object. In this case, the operator specifies a portion, seemed to be main object in the photographic frame, and repeats the adjustment operation until the adequate density of the color print is obtained. This shows the situation that it is very difficult that, on the other side in which the color negative film has the excellent light acceptance capacity (also called “dynamic range”) which can record the objective information having the high reflection factor or brightness rate, the automatic adjustment is conducted so that the specific density area of the recorded pigment image information becomes the desired density on the print paper.

Recently, a method in which the image formed in the color negative film is optically read by using the scanner, and after it is converted into the image signal, the image processing is conducted, and the digital image data is made once, is well known. On such a image signal, after various image processing represented by a negative to positive reversal processing, gradation adjustment, luminance adjustment, color balance adjustment, granular adjustment, and sharpness emphasis, are conducted, the image signal is distributed via medium such as a CD-R, floppy (R) disk, or memory card, or the internet, and outputted as the hard copy image by the silver halide printing paper, inkjet printer, or thermal printer, or displayed on the medium such as a CRT, liquid crystal display or plasma display, and appreciated.

A system used for the photo-service by which the color negative film is read by using a scanner, and a positive digital image is formed and the color print is made by using it (hereinafter, called “digital print”), and stored in the storage medium and presented, will be detailed below.

After the transmitted light information from the light source irradiated onto the color negative film is received by the image sensor, the signal processing from the analog to the digital by the AD converter is conducted. The number of samplings in this case is expressed by the bit width, and the larger the bit width is (for example, 16 bits=65536 gradations), the thicker the sampling interval is, and the sufficient information amount and the accuracy which are required for the processing for forming the positive image are given. This is important in the meaning by which, particularly in the partial gradation expansion or steeping processing, the discretization of the gradation is prevented and the generation of noise is lowered. The obtained digital signal is converted from the transmission scale to the density scale, and after various processing such as negative positive reversing and gradation adjustment are conducted, it is recorded on the printing paper by using a digital exposure unit whose light source is an LED light source or semiconductor laser. On the one hand, for the storage medium in which the digital image data is stored and presented to the customer, the digital image data with a small number of bits or reduced bit width (for example 1,500 thousands pixels, 8 bits=256 gradations) is used.

The digital image data is via the adjustment process by which, from the pigment image information of the wide density area which is recorded in the color negative film, the specific density area is reproduced to a desired gradation on the output device such as the CRT, in the same manner as the color print formed in the same manner as the conventional analog method. Accordingly, when the gradation of the digital image data is corrected by a customer itself so that it becomes the desired color image by using the retouch function of the application software (for example, Photoshop made by Adobe co.), because whole object information which is recorded by the color negative film is not possessed already, it results in a cause of the phenomenon of white compression (in the case of 8 bits=255), namely, a lack of gradation at bright areas, or fill-in (in the case of 8 bits=0), namely, a lack of gradation at shadow areas, in the displayed image.

In Japanese Tokkaihei No. 10-13680, a method is disclosed by which the image status is judged from the image information, and corresponding to the image information and judged image status, the intermediate density portion of the image is not changed, and the processing condition for respectively independently non-linearly compressing or extending the low density portion and/or high density portion of the image is set, and by generating the output image information by conducting the image processing corresponding to this processing condition, the adequate image information processing corresponding to the status of the image photographed on the film such as over/under exposure, rear-light or strobe photographing, is conducted, and the adequately finished print is stably obtained.

In Japanese Tokkaihei No. 11-53535, a method is disclosed by which the density histogram is formed from the original image, and density range is calculated, and next, the dynamic range compression extension rate α is calculated, and after a blurred image 1 generated by the median filter (MF) from the original image and a blurred image 2 generated by the low pass filter (LPF) are weighed and added each other, the blurred image is generated by compression extension by using the previously calculated compression extension rate α and by subtracting the finally obtained blurred image from the original image, even when it is the image with the high contrast and wide dynamic range as the rear-light and strobe photographing image, or the low contrast and narrow dynamic range image as the photographing image at the cloudy time, the reproduction image with the stable and adequate high image quality is obtained.

In Japanese Tokkaihei No. 2001-245153, by selecting the 1 or more basic compression (extension) characteristics from the predetermined plurality of basic compression (extension) characteristics, an image processing method by which the dodging processing which can eliminate the white compression or fill-in of the bright portion in the flash photographing or rear-light scene, can be conducted in a shorter processing time, is disclosed.

These methods relate to the method for processing the adequate color print stably or in a short time, but not to the technology relating to the substitute of the color negative film by which, to the digital image data presented to the user, the information to increase the retouch property by the hand of the user itself is newly added or even when there is no developed color negative film, the equivalent information can be obtained.

Further, in Japanese Tokkai No. 2000-152279 and U.S. Pat. No. 6,301,393, in the specific image input and output system having the device dependent type color space, the method by which the color difference to the device not-dependent type color space (for example, CIE L*a*b*, XYZ) which is not depend on the device, is extracted and stored as the deference file, is disclosed. This relates to the interchangeability of the device using the device dependent type color specification system to the other display apparatus, and not to the method by which the color negative film information of larger pieces than that of the conventional method is extracted and can be provided.

In Japanese Tokkaihei No. 10-79854, Tokkahei No. 10-191055, Tokkaihei No. 11-266358 and Tokkai No. 2000-196890, various methods by which the specified object position is adjusted to the adequate brightness, are disclosed. They are methods by which the accuracy to stably generate the digital image data used for the color print formation is increased, and not the method by which the larger pieces of color negative film information are extracted and can be provided.

The Flash Pix Format by which the digital image data separated by the resolving power is accommodated in one file, is well known. Because the application software can access to the image data with the necessary resolving power, it is not necessary that the access is made to the data with the maximum resolving power and the whole is developed to the memory as the conventional one, and corresponding to the object or output device, the decrease of the operation process to change the resolving power is attained. Each resolving power has the hierarchy structure in which the number of pixels is reduced by every 1/4, however, the number of bits, or gradation setting is the same, and the more expanded object information than the image format with one resolving power can not be provided.

In the positive image formation process by which the digital image data is obtained from the negative film, although it temporarily has the large pieces of object information recorded in the negative film, the digital image data which is stored in the storage medium such as CD-R and provided to the user, in the same manner as the color print or digital print made by the analog method, has only the gradation information which is one-sidedly optimized to the output device.

### SUMMARY OF THE INVENTION

To overcome the abovementioned drawbacks in conventional methods for processing the digital image data, it is an object of the present invention to provide a method for processing the digital image data, which make it possible to improve the retouch property of the digital image data and to substitute the image formed by the digital image data for the developed negative film, by giving image information, being equivalent to those included in the negative film, to the digital image data to be stored in the storage medium, which is provided for the user.

Accordingly, to overcome the cited shortcomings, the abovementioned object of the present invention can be attained by methods for processing digital image data described as follow.

(1) A method for processing digital image data to be stored in a storage medium, the digital image data being created by applying a predetermined image-processing to original image data, which are read and converted from a visible pigment image through an image-inputting device after developing the visible pigment image on a silver-halide photosensitive material processed by an image-wise exposing operation, the method comprising the steps of: designating an output-gradation number of the digital image data to be stored in the storage medium; retrieving a gradation-setting data set, corresponding to the output-gradation number designated in the designating step, from a plurality of gradation-setting data sets, each of which corresponds to each of a plurality of output-gradation numbers established in advance; and adjusting a gradation characteristic of the digital image data, based on the gradation-setting data set retrieved in the retrieving step.

(2) The method of item 1, wherein the output-gradation number is designated by a user through an interface of a terminal processing device.

(3) The method of item 1, wherein each of the retrieving step and the adjusting step is performed on either hardware or software.

(4) The method of item 1, wherein each of the plurality of output-gradation numbers corresponds to each of 8-bit, 10-bit, 12-bit, 14-bit and 16-bit.

(5) A method for processing digital image data to be stored in a storage medium, the digital image data being created by applying a predetermined image-processing to original image data, which are read and converted from a visible pigment image through an image-inputting device after developing the visible pigment image on a silver-halide photosensitive material processed by an image-wise exposing operation, the method comprising the steps of: designating a pixel number of the digital image data to be stored in the storage medium; retrieving a gradation-setting data set, corresponding to the pixel number designated in the designating step, from a plurality of gradation-setting data sets, each of which corresponds to each of a plurality of pixel numbers established in advance; and adjusting a gradation characteristic of the digital image data, based on the gradation-setting data set retrieved in the retrieving step.

(6) The method of item 5, wherein the pixel number is designated by a user through an interface of a terminal processing device.

(7) The method of item 5, wherein each of the retrieving step and the adjusting step is performed on either hardware or software.

(8) The method of item 5, wherein each of the plurality of pixel numbers corresponds to each of image sizes having resolutions of 300 dpi, 600 dpi and 1200 dpi.

(9) A method for processing digital image data to be stored in a storage medium, the digital image data being created by applying a predetermined image-processing to original image data, which are read and converted from a visible pigment image through an image-inputting device after developing the visible pigment image on a silver-halide photosensitive material processed by an image-wise exposing operation, the method comprising the steps of: designating a combination of an output-gradation number and a pixel number of the digital image data to be stored in the storage medium; retrieving a gradation-setting data set, corresponding to the combination of the output-gradation number and the pixel number designated in the designating step, from a plurality of gradation-setting data sets, each of which corresponds to each of combinations of output-gradation numbers and pixel numbers, the combinations being established in advance; and adjusting a gradation of the digital image data, based on the gradation-setting data set retrieved in the retrieving step.

(10) The method of item 9, wherein the combination of the output-gradation number and the pixel number is designated by a user through an interface of a terminal processing device.

(11) The method of item 9, wherein each of the retrieving step and the adjusting step is performed on either hardware or software.

(12) The method of item 9, wherein the output-gradation number corresponds to 8-bit, 10-bit, 12-bit, 14-bit or 16and the pixel number corresponds to an image size having a resolution of 300 dpi, 600 dpi or 1200 dpi.

(13) A method for processing digital image data to be stored in a storage medium, the digital image data being created by applying a predetermined image-processing to original image data, which are read and converted from a visible pigment image through an image-inputting device after developing the visible pigment image on a silver-halide photosensitive material processed by an image-wise exposing operation, the method comprising the steps of: storing both the digital image data and the original image data in the storage medium; extracting necessary information from the original image data stored in the storage medium; and applying an image-processing operation, for increasing and/or changing information content of the digital image data on the basis of the necessary information extracted from the original image data, to the digital image data read from the storage medium.

(14) The method of item 13, wherein, in the storing step, an attached file, in which at least one of contents of the predetermined image-processing applied to the original image data and information for correlating the digital image data with the original image data is/are included, is also stored in the storage medium.

(15) The method of item 13, wherein first gradation number “A” of the digital image data and second gradation number “B” of the original image data always fulfill the following first formula.

A<B

(16) The method of item 13, wherein first pixel number “C” of the digital image data and second pixel number “D” of the original image data always fulfill the following second formula.

C<D

(17) The method of item 13, wherein the predetermined image-processing and the image-processing applied in the applying step are an operation for compensating for gradation characteristics, and the necessary information are gradation information pertaining to the gradation characteristics.

(18) The method of item 13, wherein the applying step is performed under an operating program of an attached application software stored in the storage medium.

(19) A method for processing digital image data to be stored in a storage medium, the digital image data being created by applying a predetermined image-processing to original image data, which are read and converted from a visible pigment image through an image-inputting device after developing the visible pigment image on a silver-halide photosensitive material processed by an image-wise exposing operation, the method comprising the steps of: storing both the digital image data and the original image data in the storage medium; creating differential-component data between the digital image data and the original image data, both stored in the storage medium; extracting necessary information from the differential-component data created in the creating step; and applying an image-processing operation, for increasing and/or changing information content of the digital image data on the basis of the necessary information extracted from the original image data, to the digital image data read from the storage medium.

(20) The method of item 19, wherein, in the storing step, an attached file, in which at least one of contents of the predetermined image-processing applied to the original image data and information for correlating the digital image data with the differential-component data is/are included, is also stored in the storage medium.

(21) The method of item 19, wherein the predetermined image-processing and the image-processing applied in the applying step are an operation for compensating for gradation characteristics, and the necessary information are gradation information pertaining to the gradation characteristics.

(22) The method of item 19, wherein the applying step is performed under an operating program of an attached application software stored in the storage medium.

(23) A method for processing digital image data to be stored in a storage medium, the digital image data being created by applying a first predetermined image-processing to original image data, which are read and converted from a visible pigment image through an image-inputting device after developing the visible pigment image on a silver-halide photosensitive material processed by an image-wise exposing operation, the method comprising the steps of: storing both the digital image data and sub-original image data in the storage medium, the sub-original image data being created by applying a second predetermined image-processing to the original image data; extracting necessary information from the sub-original image data stored in the storage medium; and applying an image-processing operation, for increasing and/or changing information content of the digital image data on the basis of the necessary information extracted from the original image data, to the digital image data read from the storage medium.

(24) The method of item 23, wherein, in the storing step, an attached file, in which at least one of contents of the first predetermined image-processing applied to the original image data, contents of the second predetermined image-processing applied to the original image data and information for correlating the digital image data with the original image data is/are included, is also stored in the storage medium.

(25) The method of item 23, wherein first gradation number “A” of the digital image data and second gradation number “E” of the sub-original image data always fulfill the following third formula.

A<E

(26) The method of item 23, wherein first pixel number “C” of the digital image data and second pixel number “F” of the sub-original image data always fulfill the following fourth formula.

C<F

(27) The method of item 23, wherein the first predetermined image-processing, the second predetermined image-processing and the image-processing applied in the applying step are an operation for compensating for gradation characteristics, and the necessary information are gradation information pertaining to the gradation characteristics.

(28) The method of item 23, wherein the applying step is performed under an operating program of an attached application software stored in the storage medium.

Further, to overcome the abovementioned problems, other image forming methods, embodied in the present invention, will be described as follow:

(29) An image forming method characterized in that,

in the image forming method for outputting digital image data, to which a predetermined image-processing is applied, to a storage medium, after reading a visible pigment image, which is developed on a silver-halide photosensitive material processed by an image-wise exposing operation, and converting it into electronic signals,

the gradation of the digital image data is changed, corresponding to an output-gradation number of the digital image data.

According to the method described in item 1 or 29, it becomes possible to produce a high-quality digital prints better than ever, and it also becomes possible for a customer to apply image-processing by himself so as to obtain desired digital image data.

In the image forming method described in item 29, the meaning of the description of “the gradation of the digital image data is changed, corresponding to an output-gradation number of the digital image data” is to correlate the output-gradation number of the digital image data outputted by the scanner (for instance, 8-bit, 10-bit, 12-bit, 14-bit, 16-bit, etc.) with the information content included in the negative film (the harder the image contrast becomes, the lower the density of the information content decrease), which is generated by the difference between gradation-setting values (for instance, a compensated gradation-setting value of γ=2.2 for CRT display use and a gradation-setting value of γ=1.0 for ink-jet printer outputting use).

Concretely speaking, the image to be outputted at a low bit number is outputted as it is a low γ value (soft contrast), while the image to be outputted at a high bit number is outputted with a high γ value (hard contrast). According to the present invention, it is desirable that the image to be outputted at a low bit number is outputted with a high γ value (hard contrast), while the image to be outputted at a high bit number is outputted with a low γ value (soft contrast). This is because, this make it possible to keep the digital image data in a low compensated state (keeping a larger contents of information included in the negative film).

The meaning of “gradation-setting” is to adjust the γ value of the digital image data at a value suitable for the outputting medium, such as a silver-halide photosensitive paper, a CRT monitor, etc., by employing transmissive information of pigment density colored on the negative film and to adjust the brightness of the main subject at a most suitable value in the photographing situation with a strobe or a rear light scene.

Further, the meaning of “output-gradation number” is a number of gradation steps to be expressed by the digital image data. For instance, the output-gradation number of 16-bit indicates 65536 gradation steps, and the output-gradation number of 8-bit indicates 256 gradation steps.

Since the developed color density considerably varies with exposing conditions, such as under or over exposure photographing situations, etc., an exposure controlling operation is generally conducted in order to adjust output values at most suitable values, by changing the intensity of the light source of the scanner, the sensitivity of the CCD sensor and the reading time. Only by applying the negative-to-positive reversing operation to the transmissive information of pigment density colored on the negative film, for which the output values are optimized, after converting it to the density scale, the gradation characteristic of the negative film remains as it is, resulting in a soft contrast. As for the CRT monitor, the gradation characteristic is generally compensated for at γ=2.2, being a γ value of the sRGB standard. As a result, shading parts or highlighted parts are compressed due to the high contrast processing.

In case of the photographing operation with the strobe or in the rear light scene, since both the high density region and the low density region reside within one photographed frame of the negative film, when the high contrast processing mentioned above is applied, an extremely compressed density area or a density area to be cut off would be differ depending on a position of density area, which is set as a brightness center of the positive image (normally, a main subject area) on the negative film. It is desirable that such the extremely compressed density area or a density area to be cut off should be as small as possible, since such the density area is apt to impede reapplication of a certain image-processing. Concretely speaking, in such the case of the photographing operation with the strobe or in the rear light scene, when it is difficult to set the brightness center of the positive image (normally, a main subject area) at an optimum position in the density area of the negative film, and therefore, the optimization probability is low, it is desirable that the digital image data is outputted to a storage medium before applying the gradation-setting operation or at an initial stage as earlier as possible, assuming that a certain image-processing would be further applied to the digital image data, stored in the storage medium, later on. Further, it is desirable that the output-gradation number of the digital image data, before applying the gradation-setting operation or at an initial stage, is as large as possible, in order to maintain the accuracy when a certain image-processing will be further applied.

(30) An image forming method characterized in that,

in the image forming method for outputting digital image data, to which a predetermined image-processing is applied, to a storage medium, after reading a visible pigment image, which is developed on a silver-halide photosensitive material processed by an image-wise exposing operation, and converting it into electronic signals,

the gradation of the digital image data is changed, corresponding to an output-pixel number of the digital image data.

According to the method described in item 5 or 30, it becomes possible to produce a high-quality digital prints better than ever, and it also becomes possible for a customer to apply image-processing by himself so as to obtain desired digital image data, as well as the method described in item 1 or 29.

In the image forming method described in item 30, the meaning of the description of “the gradation of the digital image data is changed, corresponding to an output-pixel number of the digital image data” is to correlate the output-pixel number of the digital image data outputted by the scanner with the information content included in the negative film, which is generated by the difference between gradation-setting values. Further, it is desirable that the output-pixel number of the digital image data, before applying the gradation-setting operation or at an initial stage, is as large as possible, in order to maintain the accuracy when a certain image-processing will be further applied.

(31) An image forming method characterized in that,

in the image forming method for outputting digital image data, to which a predetermined image-processing is applied, to a storage medium, after reading a visible pigment image, which is developed on a silver-halide photosensitive material processed by an image-wise exposing operation, and converting it into electronic signals,

the gradation of the digital image data is changed, corresponding to an output-gradation number and an output-pixel number of the digital image data.

According to the method described in item 9 or 31, it becomes possible to produce a high-quality digital prints better than ever, and it also becomes possible for a customer to apply image-processing by himself so as to obtain desired digital image data, as well as the method described in item 1 or 29.

In the image forming method described in item 31, the meaning of the description of “the gradation of the digital image data is changed, corresponding to an output-gradation number and an output-pixel number of the digital image data” is to correlate the output-gradation number and the output-pixel number of the digital image data outputted by the scanner with the information content included in the negative film, which is generated by the difference between gradation-setting values. Further, it is desirable that both the output-gradation number and the output-pixel number of the digital image data, before applying the gradation-setting operation or at an initial stage, is as large as possible, in order to maintain the accuracy when a certain image-processing will be further applied.

(32) An image forming method characterized in that:

in the image forming method by which, after the image wise exposed silver halide photographic photosensitive material is developing processed, and the visualized pigment image information is read through the image input medium and converted into the electric signal, the digital image data on which a predetermined image processing is conducted is outputted to the storage medium,

it is structured such that, together with the digital image data on which the predetermined image processing is conducted, the digital image data before the predetermined image processing is conducted, is outputted; and by a means for extracting and supplementing the necessary information from the digital image data before the predetermined image processing is conducted, the addition and change of the predetermined image processing on the digital image data on which the predetermined image processing is conducted, can be conducted even after it is outputted to the storage medium.

(33) An image forming method characterized in that:

in the image forming method in which, after the image wise exposed silver halide photographic photosensitive material is developing processed, and the visualized pigment image information is read through the image input medium and converted into the electric signal, the digital image data on which the predetermined image processing is conducted is outputted to the storage medium,

it is structured such that, together with the digital image data on which the predetermined image processing is conducted, the difference data between the digital image data before the predetermined image processing is conducted, and the digital image data on which the predetermined image processing is conducted, is made, and by the means by which the necessary information is extracted and supplemented, the addition•change of the predetermined image processing to the digital image data on which the predetermined image processing is conducted, can be conducted even after it is outputted to the storage medium.

(34) An image forming method characterized in that:

in the image forming method in which, after the image wise exposed silver halide photographic photosensitive material is developing processed, and the visualized pigment image information is read through the image input medium and converted into the electric signal, the digital image data on which the predetermined image processing is conducted is outputted to the storage medium,

it is structured such that, together with the digital image data on which the predetermined image processing is conducted, the digital image data in which the application amount of at least one predetermined image processing is different, is outputted, and by the means by which the necessary information is extracted and supplemented from the digital image data in which the application amount of at least one predetermined image processing is different, the addition•change of the predetermined image processing to the digital image data on which the predetermined image processing is conducted, can be conducted even after it is outputted to the storage medium.

The image forming methods, embodied in the present invention and described in items 32-34, relate to the digital image forming method by which the digital image data before the predetermined image processing is conducted or the initial digital image data, as early as possible, is outputted so that the high quality digital print is made or the customer itself conducts the image processing and the desired digital image data can be obtained.

The image forming methods, embodied in the present invention and described in item 32, is characterized in that: before the predetermined image processing is conducted, that is, the processing to form the optimum image quality on the output device such as silver halide paper or CRT monitor, specifically, the digital image data on which all processing of the negative positive reversing, gradation compensation, luminance adjustment, color balance adjustment, granular adjustment, and sharpness emphasis are not conducted, is outputted. Further, the fifth image forming method of the present invention is characterized in that: the difference data between the digital image data before the predetermined image processing is conducted, and the digital image data on which the predetermined image processing is conducted is outputted. That is, the sixth image forming method of the present invention is characterized in that: the application amount of the predetermined image processing is different, that is, the processing to form the optimum image on the output device such as the silver halide paper or CRT monitor, specifically, the digital image data in which the processing amount of the negative positive reversing, gradation correction, luminance adjustment, color balance adjustment, granular adjustment, and sharpness emphasis, is different, is outputted.

In the image forming methods, embodied in the present invention and described in items 32-34, “the necessary information is extracted and supplemented from digital image data on which the predetermined image processing is conducted” means that, in the strobe photographing or rear-light scene, the center of the brightness of the positive image (normally, main object area) is not the optimum, for example, when the image processing is conducted again by the customer itself, before the gradation setting is conducted, or by using all of the initial, as possible, digital image data, or the information of a portion, newly or the digital image data whose shortage portion is supplemented, is formed. Further, “a means for extracting and supplementing the necessary information from the digital image data before the predetermined image processing is conducted” means, before the gradation setting is conducted, or by using all of the initial, as possible, digital image data, or the information of a portion, the program for newly forming the digital image data or the program for forming the digital image data whose shortage portion is supplemented, or the plug-in of the exclusive use application, or the other application software. Further, it may also be the application software attached in the storage medium.

The image forming methods, embodied in the present invention and described in items 32-34, may also attach the attached file in which at least one of the information for correlating the content of the predetermined image processing conducted on the digital image data and the digital image data on which the predetermined image processing is conducted with the digital image data before the predetermined image processing is conducted, is recorded, in the storage medium.

“The digital image data before the predetermined image processing is conducted” in the image forming methods, embodied in the present invention and described in item 32, “difference data” in the image forming methods, embodied in the present invention and described in item 33, and “the digital image data whose application amount of the predetermined image processing is different” in the image forming methods, embodied in the present invention and described in item 34, may also be another file different from “the digital image data on which the predetermined image processing is conducted”, or the same file. In the case where it is stored in the same file, TIFF, Exif and Flash Pix is used. By the use of tag (“meta-data”), 2 digital image data can be respectively independently read. In this case, it is necessary that “the means for extracting the necessary information from the digital image data before the predetermined image processing is conducted, and supplementing it” which is represented by the plug-in of the program, exclusive use application, or the other application software, can use the image tag. Particularly, in the sixth image forming method of the present invention, it is preferable that, when not less than 2 “digital image data whose application amount of the predetermined image processing is different” are used, it is formed as one file.

In the image forming method, embodied in the present invention and described in item 32, it is preferable that the number of gradations (A) of the digital image data on which the predetermined image processing is conducted, and the number of gradations (B) of the digital image data before the predetermined image processing is conducted, are always A<B. For example, when A is 8 bits, it is preferable that B is 10 bits, 12 bits are more preferable, and 16 bits are further preferable.

Further, in the image forming method, embodied in the present invention and described in item 32, it is preferable that the number of the pixels (C) of the digital image data on which the predetermined image processing is conducted, and the number of the pixels (D) of the digital image data before the predetermined image processing is conducted, are always C<D. For example, when C is 1,500 thousand pixels, it is preferable that D is 3,000 thousand pixels, 4,500 thousand pixels are more preferable, and 6,000 thousand pixels are further preferable.

In the image forming method, embodied in the present invention and described in item 34, it is preferable that the number of gradations (A) of the digital image data on which the predetermined image processing is conducted, and the number of gradations (E) of the digital image data in which the application amount of the predetermined image processing is different, are always A<E. For example, when A is 8 bits, it is preferable that E is 10 bits, 12 bits are more preferable, and 16 bits are further preferable.

Further, in the image forming method, embodied in the present invention and described in item 34, it is preferable that the number of pixels (C) of the digital image data on which the predetermined image processing is conducted, and the number of pixels (F) of the digital image data in which the application amount of the predetermined image processing is different, are always C<F. For example, when C is 1,500 thousand pixels, it is preferable that F is 3,000 thousand pixels, 4,500 thousand pixels are more preferable, and 6,000 thousand pixels are further preferable.

The matters common to the image forming methods, embodied in the present invention, will be detailed in the following.

As the “silver halide photographic photosensitive material (hereinafter, called also negative film, or film)” in the present invention, the conventional color negative film (for example, Konica Co. made Centuria series) is listed. Further, it may also be the exclusive use color negative film which is designed so that it is more adapted to the film scanner reading, in which the print operation by the projection exposure onto the printing paper by using the analog printer like the conventional color negative film, is not made the presupposition. As the exclusive use color negative film, for example, as described in Japanese Tokkai No. 2000-310841, in order to extract the brightness information and color information of the digital image data, the film which has the photosensitive layer in which the bright ness information is recorded, preferably, independently has the photosensitive layer in which the color information is further recorded, or as described in the specification of Japanese Tokugan No. 2000-33492, the mode which has the spectral sensitivity characteristics in which the visual characteristic of human eyes is imitated, or the sensitivity balance, is listed.

In the present invention, “development processing” may also be either one of the liquid development processing which is called “C-41 processing” used for the color negative film processing, or the thermal development processing by which the processing sheet in which the development agent is built-in, is pasted together with the film after the film is swelled by the water, and is pressure contacted and heat processed by the heat block or drum.

In the present invention, the color negative film on which the image wise exposure according to the present invention is conducted, can be processed by using the rack and tank or the processing tank which is publicly known in the relevant technological field as the low capacity thin type tank processing system (LVTT) having the automatic tray design. Particularly, as the preferred example of such a processing method and apparatus, it is described in detail in Japanese Tokkaihei No. 8-44006.

Further, in the present invention, on the color negative film on which the image wise exposure according to the present invention is conducted, un-desilverization processing may be conducted. The un-desilverization processing means that the breaching and fixing processing in the development processing process of the color negative film on which the image wise exposure is conducted, is completed in the non-perfect state, or in the state which is not perfectly conducted, that is, it means the processing system by which, when the developing is conducted by using the aromatic first class amine developing agent, the development processing process is completed in the sate in which the metallic silver (development silver) which is generated by developing the exposed silver halide particle by the developing agent, and un-reacted silver halide particle are remained. Hereupon, there is a possibility that the un-reacted silver halide is changed into the metallic silver (development silver) by the light irradiation at the time of the photoelectric conversion by using the scanner.

In the present invention, “image input medium” means, specifically, an image pick-up element (image sensor) having the photoelectric conversion function, and an image pick-up element (CCD type image pick-up element, hereinafter, simply called also “CCD”) in which the structure having the charge transfer mechanism called CCD (charge coupled device) is adopted particularly in the shift register (charge transfer mechanism) is well known. In the CCD, there is a line-like CCD which is arranged in one dimension, and an area type CCD which is arranged in the two dimension. When the line-like CCD is used, the scanning mechanism by which the color negative film is conveyed in the constant direction and all the photographing frame is read is necessary, and in order to reduce the time necessary for reading, it is also preferable that the area-like CCD is used in the present invention.

In the present invention, “is read through the image input medium, and converted into the electric signal” means the process in which each pigment amount (“each pigment image information”) of yellow, magenta, and cyan, generated respectively corresponding to 3 primary color component of red, green, and blue which are color (“image”) information of the object recorded in the color negative film, and the optical density information (for example, infrared image information) other than each pigment amount are replaced with the electric signal information by using the image input medium, light source and color separation filter.

In the present invention, “the predetermined image processing” means the processing by which, because the obtained electric signal information is simply the transmission information of the colored pigment density of the color negative film, it is made the optimum image quality on the output device such as the silver halide paper, or CRT monitor. Specifically, the negative positive reversing, gradation correction, luminance adjustment, color balance adjustment, granular adjustment, and sharpness emphasis are listed. Further, the information generated from the reading through “a predetermined image processing”, is called “digital image data”.

In the present invention, “the storage medium” is a memory in which the “digital image data” is stored. As the memory, it may also be any one of the scanner main body, digital mini-lab in which the scanner is mounted, memory provided in the inside of the processing terminal equipment to which the scanner is connected, or portable memory such as a MO or CD-R.

In the present invention, the “image forming method” means the process until the digital image data formed through the “predetermined image processing” is stored in the “storage medium”, from the reading.

In the present invention, “addition•change” indicates the processing to make it the optimum image quality as in the same manner as the “predetermined image processing”. The “addition” means both of that the predetermined image processing is redundantly conducted, or the omitted processing is initially conducted. “Change” means that the application amount is changed and the “predetermined image processing” is conducted again. In the present invention, it is preferable to attain the object of the present invention that the “predetermined processing” and the “addition•change” are particularly the gradation correction processing.

In the present invention, the “digital image data” can apply various compression methods. For example, an arbitrary method is selected from the JPEG compression method according to the DCT (discrete cosine transformation) and it can be used. As the compression method of the digital image data, the methods according to the difference pulse code conversion, vector quantization, wavelet, and fractal are well known. By the compression method, there is a case where a slight error is generated by the compression. Therefore, in the “digital image data before the predetermined image processing is conducted” in the image forming method, embodied in the present invention and described in item 32, the “difference data” in the image forming method, embodied in the present invention and described in item 33, and the “digital image data whose application amount of the predetermined image processing is different” in the image forming method, embodied in the present invention and described in item 34, it is preferable that the compressibility is respectively set low to the “digital image data on which the predetermined image processing is conducted”.

### BRIEF DESCRIPTION OF THE DRAWINGS

Other objects and advantages of the present invention will become apparent upon reading the following detailed description and upon reference to the drawings in which:

FIG. 1 is a flow chart showing the flow of an embodiment of an image forming method of the present invention;

FIG. 2 is a flow chart showing the flow of an embodiment of the image forming method of the present invention;

FIG. 3 is a flow chart showing the flow of another embodiment of the image forming method of the present invention;

FIG. 4 is a flow chart showing the flow of another embodiment of the image forming method of the present invention;

FIG. 5 is a view showing the histogram of the 16-bit output digital image data;

FIG. 6 is a view showing the histogram of the digital image data after the logarithmic conversion (S8) processing is conducted on the 16-bit output digital image data; and

FIG. 7 is a view showing the histogram of the digital image data after the gradation adjustment (S11) and the luminance adjustment (S12) are further conducted on the digital image data after the logarithmic conversion (S8) processing is conducted on the 16-bit output digital image data.

### DETAILED DESCRIPTION OF THE PREFERRED EMBODIMENT

Referring to the drawings, a specific embodiment of an image forming method of the present invention will be described below.

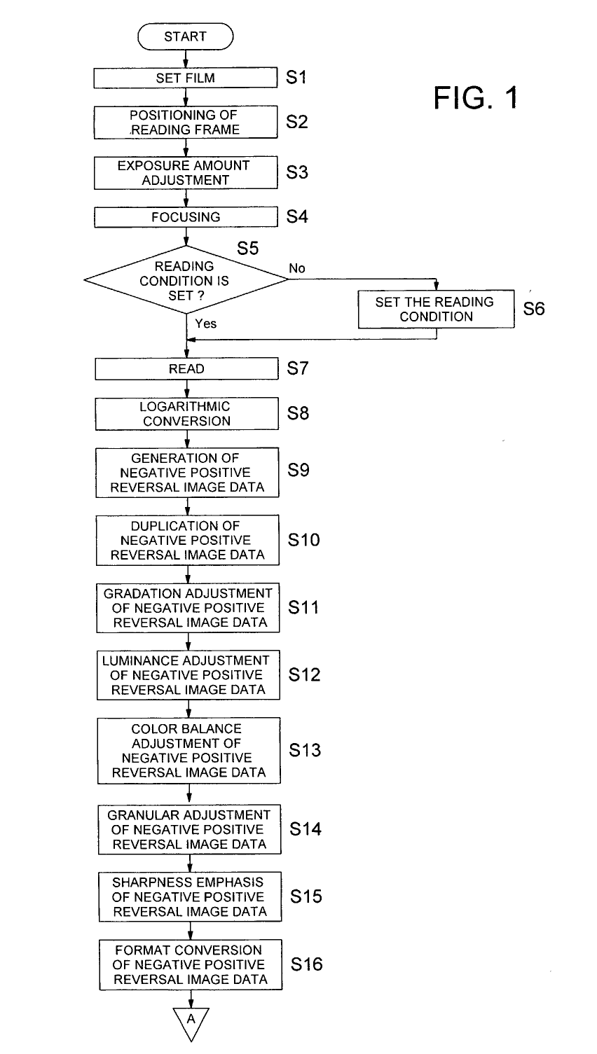

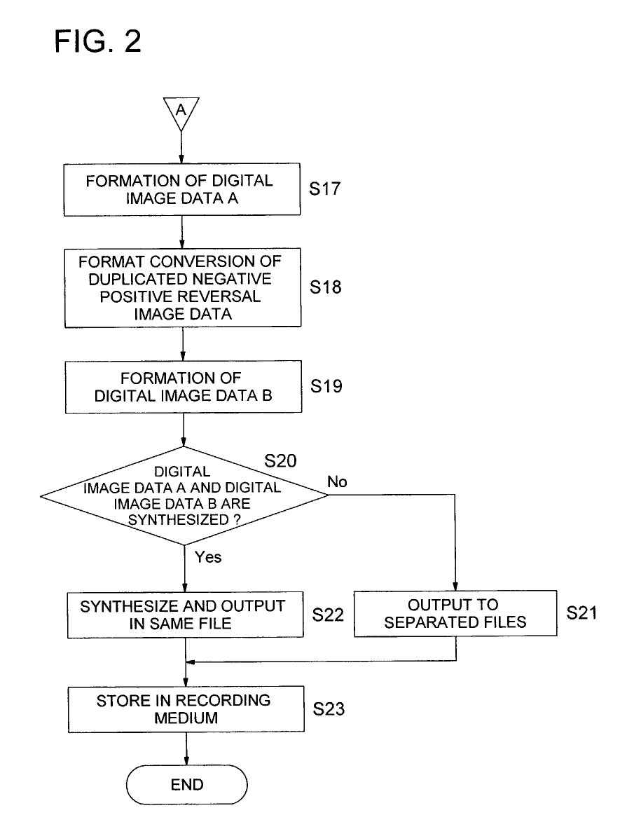

FIG. 1 and FIG. 2 are flow charts showing the flow of an embodiment of an image forming method of the present invention. When the negative film is set in a scanner apparatus (S1), after the positioning of the reading frame (S2), the exposure amount adjustment (S3) for optimizing the reading condition from the density information of the reading frame is conducted. A means for the exposure amount adjustment may use any one of the change of the intensity of the scanner light source, the sensitivity of the CCD, or reading time. Because the sensitivity of the CCD or reading time adjustment is a cause of the increase of the noise amount or the lowering of the processing efficiency, it is preferable that the light source intensity (brightness) is made the adjustment means. The reading condition setting on the scanner apparatus side is completed by the focusing (S4). When the reading condition is not set, the reading condition is set (S6) when the user operates the scanner apparatus by the interface function of the application software of the scanner apparatus. Alternatively, it may be a reading system by which the reading condition is previously formed as the setting file, and the setting file is read at the time of scanner apparatus movement. As the embodiment of the present invention, a mode in which “yes or no” of the use is switched, by selecting the reading condition from the previously provided items at the time of reading condition setting, or by inputting it, is listed.

In the first image forming method, the number of the output bits is selected. In the second image forming method of the present invention, the reading resolution is selected. In the third image forming method of the present invention, the number of output bits and reading resolution are selected. Further, when the first-third image forming methods of the present invention are conducted, at each condition setting of the number of output bits, reading resolution, or both of them, it is preferable that it is a mode in which the execution of the present invention which changes the gradation setting, and the case where gradation setting is not changed, can be selected. Further, the interface function by which the gradation setting is arbitrarily set, may be provided.

When the fourth and the fifth image forming methods of the present invention are conducted, it may also be structured such that the “yes or no” of the execution of the gradation adjustment (S11) such as the gradation correction, luminance adjustment (S12), color balance adjustment (S13), granular adjustment such as the granular removal (S14), and sharpness emphasis (S15) in the processing after the reading (S7), or processing condition can be individually set.

When the sixth image forming method of the present invention is conducted, it is structured such that the “yes or no” of the execution of the gradation adjustment (S11) such as the gradation correction, luminance adjustment (S12), color balance adjustment (S13), granular adjustment such as the granular removal (S14), and sharpness emphasis (S15) in the processing after the reading (S7), or processing condition can be individually set. Further, when a plurality of processing conditions are set and a plurality of digital image data are formed, it is desirable that the interface function to simplify it is given.

When the gradation adjustment (S11) is fixed, it is set to γ value 2.2 regulated in the CRT monitor, particularly, sRGB. As the mode when the gradation adjustment (S11) can be corrected, an interface function by which the input column of the γ value, color bar, or tone curve is displayed, and it is corrected to an arbitrary curve shape by using the pointing device, can be listed.

The luminance adjustment (S12) is a function to automatically adjust the brightness of the whole body, and particularly, the brightness is optimized in the vicinity of the main object. In the strobe scene or rear-light scene, because it is difficult that the brightness in the vicinity of the main object is optimized, it is desirable that the scene discrimination using the pattern matching function, specific color (skin-color, sky-color, or gray) extraction, or the function to extract the characteristic of the image structure is given. As the mode of the case where the luminance adjustment (S12) can be corrected, the interface function by which the input column of the brightness value, color bar, or tone curve is displayed, and it is corrected to an arbitrary brightness by using the pointing device, is listed.

The color balance adjustment (S13) the function by which the intensity of the RGB signal is approximated, and it is adjusted to the color balance near the observation condition at the time of the photographing, and the correction of the color temperature or the lighting condition at the time of photographing is included. In the case of general scenes, the average value of the RGB signal of the whole image approximates to gray, however, in the photographing under the fluorescent lump, or when the ratio in which the object such as red occupies the whole image plane, is increased, the approximation accuracy is greatly lowered. As the mode in which the color balance (S13) can be corrected, the interface function by which the input column of the brightness value of the BGR, color bar, or tone curve is displayed, and it is corrected to an arbitrary balance by using the pointing device, is listed.

Next, the granular adjustment (S14) of the negative positive reversal image data will be detailed. As the removal method of the noise included in the image signal, the method of smoothing•median filter is widely known (for example, The practical image processing learned in C-language, on page 54, published by OHM Co, under joint authorship with Masayoshi Inoue, Nobuyuki Yagi, Eisuke Nakasu, Koji Mitani, and Mashato Okui). The median filter is expressed by the following expression.

Kij1=median(Kmn)

(m,n)∈N(Kij)

In the expression, Kij1 expresses the target pixel density value after the image processing, and Kmn expresses the target pixel density value before the processing, and Kij expresses the density value of the target pixel.

The median filter is a non-linear filter which outputs the median (median value) of the density value (hereinafter, called also pixel value) in a local area. As the local area, when the pixel vicinity of 3×3 matrix is assumed, the fifth density value which is the median when arranged in the order from larger one of each pixel, is outputted.

As the smoothing processing in the present invention, the median filter may also be used, or the method by which the noise is removed and decreased by using the noise removal function of the photo shop plug-in software (made by Konica co.) by which the dimension of the mask or the threshold value is changed corresponding to the noise characteristic, is listed. In this case, the processing is conducted as possible on the frequency component of the noise, and the parameter is adjusted to the adaptive amount by which so far as the object information is not removed.

Next, the sharpness emphasis (S15) of the negative positive reversal image data will be detailed. As the method of the sharpness processing of the image signal, the method of the un-sharp masking•Laplacian filter is widely known (for example, An introduction to the digital image processing, on Page 34, published by Corona co., written by Koichi Sakai). The method using the un-sharp masking which is an example of the representative sharpness processing will be described below. The un-sharp masking Hij is expressed by the following expression.

Hij=Kij2+C(Kij2−Kij3)

In the expression, Kij3 is a local average value in the pixel Kij2, and is the blurred image (the image composed of the low frequency component). (Kij2−Kij3) means that the high frequency component is taken out by subtracting the blurred image from the original image. C is a coefficient and it adjusts the degree at which the high frequency component is given, and by adding this high frequency component to the original image, the image whose high frequency area is emphasized is obtained.

When the above-described smoothing processing is excessively applied, a disadvantage such as the shadow of the vicinity of the bridge of the nose of the face is lost, the doubling-like noise is generated, and a smooth expressionless make-up face is generated, and the noise like the fine power is scattered is generated, is generated. Further, also in the case where the lowered sharpness feeling is emphasized, when excessively applied, the noise is also emphasized. In the present invention, it is preferable that the image processing method by which the granular noise signal included in the color image signal written in Japanese Tokugan No. 20001-329205 specification by which such a problem is solved, is suppressed, and in addition, the sharpness of the image can be emphasized, and in which the calculation load is small, is used.

The image processing method is a method by which, in order to divide the image by the frequency band, the multi-resolution conversion is conducted, and the smoothing processing or sharpness processing is conducted for each divided frequency band. The multi-resolution conversion is a general name of the method represented by the wavelet conversion•perfect restructure filter-bank•Laplacian pyramid, and by one-time conversion operation, the separation into the low frequency component and the high frequency component, and the down-sampling (the number of pixels thin-out) are conducted on the input signal, and when the same operation is repeated on the obtained low frequency component, the multi-resolution signal is obtained. Relating to such a method, the detailed explanation is made in, for example, “Wavelet analysis and filter-bank” (published by Baihukan, under joint authorship with G. Strang and T. Guen).

Referring to FIG. 1 and FIG. 2, a flow of the fourth image forming method of the present invention will be detailed below. When the logarithmic conversion (S8) is conducted on the read digital image data, the negative positive reversal image data is generated (S9). After this, the negative positive reversal image data is duplicated (S10), and on the one side negative positive reversal image data, each of processing of the gradation adjustment (S11), luminance adjustment (S12), color balance adjustment (S13), granular adjustment (S14) such as the granular removal, and format conversion (S16), is conducted, and the digital image data A is formed (S17).

On the other side negative positive reversal image data (in the case of FIG. 1 and FIG. 2, duplicated negative positive reversal image data), only the format conversion (S18) is conducted corresponding to a predetermined file format used for the output, and the digital image data B is formed (S19). The formed digital image data A and the digital image data B are separately file outputted (S21), and may also be stored (S23) in the storage medium, or after they are synthesized (S22) in the same file, it may also be stored (S23) in the storage medium.

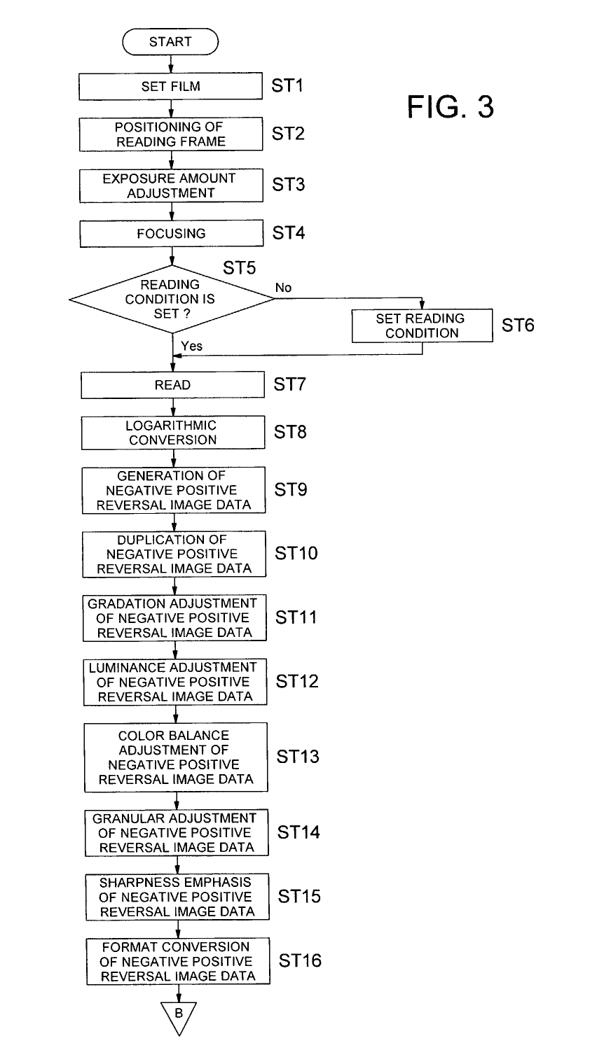

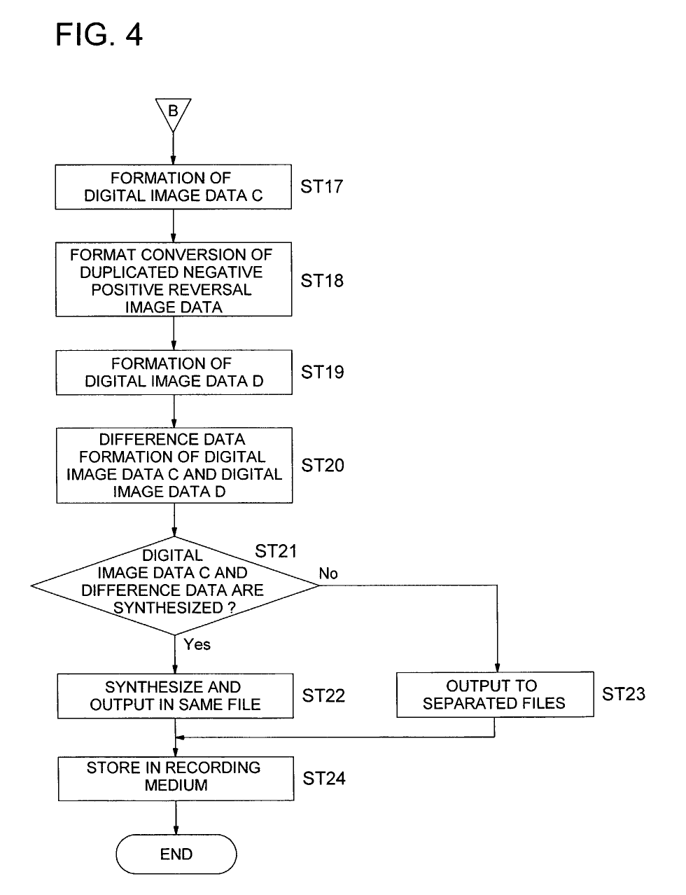

Referring to FIG. 3 and FIG. 4, a flow of the fifth image forming method of the present invention will be detailed below. FIG. 3 and FIG. 4 are flow charts showing the flow of another embodiment of the image forming method of the present invention. When the logarithmic conversion (ST8) is conducted on the read digital image data, the negative positive reversal image data is generated (ST9). After this, the negative positive reversal image data is duplicated (ST10), and on one side negative positive reversal image data, each of processing of the gradation adjustment (ST11), luminance adjustment (ST12), color balance adjustment (ST13), glanular adjustment (ST14) such as the granular removal, sharpness emphasis (ST15), and format conversion (ST16), is conducted, and the digital image data C is formed (ST17).

On the other side negative positive reversal image data (in the case of FIG. 3 and FIG. 4, the duplicated negative positive reversal image data), only the format conversion (ST18) is conducted corresponding to the predetermined file format used for the output, and the digital image data is formed (ST19). Furthermore, the difference data between the formed digital image data C and the digital image data D is made (ST20). The formed digital image data C and the difference data are separately file outputted (ST23), and may also be stored (ST24) in the storage medium, or after they are synthesized (ST22) in the same file, it may also be stored (ST24) in the storage medium.

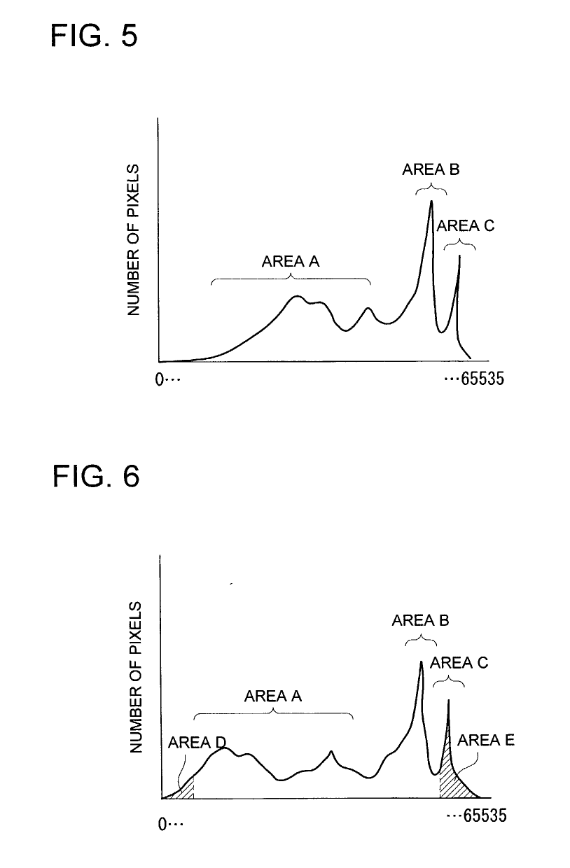

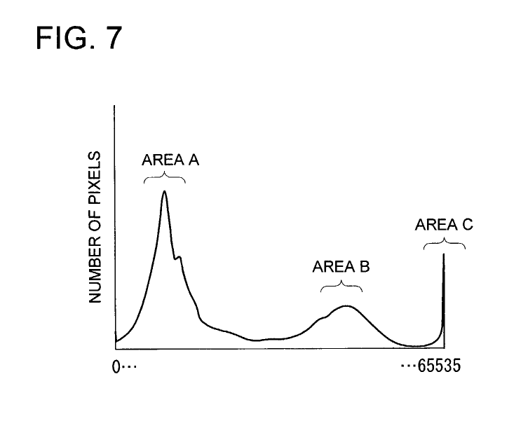

Referring to FIG. 5, FIG. 6 and FIG. 7, the gradation conversion processing according to the image forming method of the present invention will be detailed below. FIG. 5 shows a histogram of 16-bit output digital image data (electric signal information of the transmission information of the colored pixel density of the negative film) after the reading (S7) shown in FIG. 1 and FIG. 2 in the strobe proximity photographing scene. FIG. 6 shows the histogram of the digital image data after the processing of the logarithmic conversion (S8) shown in FIG. 1 and FIG. 2 is conducted on the 16-bit output digital image data. For the explanation, the negative positive reversing is omitted, and by FIG. 5, the histogram after the negative positive reversing is shown. FIG. 7 shows the histogram of the digital data after the gradation adjustment (S11) and the luminance adjustment (S12) shown in FIG. 1 and FIG. 2, are further conducted on the digital image data after the processing of the logarithmic conversion (S8) is conducted.

The gradation area shown by the area A, area B and area C in FIG. 5, FIG. 6 and FIG. 7, shows the gradation distribution for each object structure. The area A shows the area of the object structure in which the strobe light strikes slightly weakly and the background is darker than the person existing near the camera. The area B shows the object structure in which the face of the person is positioned. The area C shows the area of the object structure in which the strobe light strikes strongly on a portion of the face of the person, heir and wear, and is reflected.

In FIG. 5, while the area A is positioned near about the center of the histogram, in FIG. 6, it is distributed spreading to slightly shadow side, and in FIG. 7, the gradation area is compressed and steepened. Further, the area D in FIG. 6 is cut off in FIG. 7, and it is filled-in blackish in the image. The area C in FIG. 5 still positions in the highlight side while slightly moved to the shadow side in FIG. 6, and the area E in FIG. 6 is almost cut off in FIG. 7, and is suffered by the white compression phenomenon, namely, a lack of gradation at whitish areas in the image. The area B in FIG. 5 is still positioned in the highlight side while slightly moved to the shadow side in FIG. 6, however, in FIG. 7, it is seen that the area B is moved to the gradation considerably near the center. In FIG. 7, although the brightness of the face of the person which is a main object is optimized, the gradation of the background is compressed or the gradation loss due to the fill-in is generated. Further, in a portion on which the strobe light strongly strikes, its almost portion is suffered by the white compression phenomenon, namely, a lack of gradation at whitish areas.

The present invention is characterized in that: in the optimized image (FIG. 7) on which the image processing is conducted, the object information (area A) whose gradation is compressed, and the original image including the lost object information (area D, area E) is stored as it is; or the difference data (FIG. 7, and FIG. 5 or the difference of FIG. 6) is extracted and stored; and the original image to the optimized image (FIG. 7) are divided for each information amount, and is made one file structure.

According to the methods for processing the digital image data and the image-forming methods, embodied in the present invention, the following effects can be attained.

(1) According to the method embodied in the present invention, when the recording information corresponding to the number of gradations is given, the desired digital image data by which the retouching property by the hand of the user itself is increased, or even when the developed negative film does not exist, the equivalent information can be presented, can be provided.

(2) Further, according to the method embodied in the present invention, when the recording information of the negative film corresponding to the number of pixels is given, the desired digital image data by which the retouching property by the hand of the user itself is increased, or even when the developed negative film does not exist, the equivalent information can be presented, can be provided.

(3) Still further, according to the method embodied in the present invention, when the recording information of the negative film corresponding to the number of gradations, and the number of pixels is given, the desired digital image data by which the retouching property by the hand of the user itself is increased, or even when the developed negative film does not exist, the equivalent information can be presented, can be provided.

(4) Still further, according to the method embodied in the present invention, when, together with the digital image data on which a predetermined image processing is conducted, the digital image data before the predetermined image processing is conducted, is provided, a recording medium in which the desired digital image data is recorded, by which the retouching property by the hand of the user itself is increased, or even when the developed negative film does not exist, the equivalent information can be presented, can be provided.

(5) Still further, according to the method embodied in the present invention, when, together with the digital image data on which a predetermined image processing is conducted, the difference data between the digital image data before the predetermined image processing is conducted, and the digital image data on which the predetermined image processing is conducted, is given, a recording medium in which the desired digital image data is recorded, by which the retouching property by the hand of the user itself is increased, or even when the developed negative film does not exist, the equivalent information can be presented, can be provided.

(6) Still further, according to the method embodied in the present invention, when, together with the digital image data on which a predetermined image processing is conducted, at least one of digital image data in which the application amount of the predetermined image processing is different, is given, a recording medium in which the desired digital image data is recorded, by which the retouching property by the hand of the user itself is increased, or even when the developed negative film does not exist, the equivalent information can be presented, can be provided.

Disclosed embodiment can be varied by a skilled person without departing from the spirit and scope of the invention.

What is claimed is:

1. A method for processing digital image data to be stored in a storage medium, said digital image data being created by applying a predetermined image-processing to original image data, which are read and converted from a visible pigment image through an image-inputting device after developing said visible pigment image on a silver-halide photosensitive material processed by an image-wise exposing operation, said method comprising the steps of:
designating an output-gradation number of said digital image data to be stored in said storage medium;
retrieving a gradation-setting data set, corresponding to said output-gradation number designated in said designating step, from a plurality of gradation-setting data sets, each of which corresponds to each of a plurality of output-gradation numbers established in advance; and
adjusting a gradation characteristic of said digital image data, based on said gradation-setting data set retrieved in said retrieving step.

2. The method of claim 1,
wherein said output-gradation number is designated by a user through an interface of a terminal processing device.

3. The method of claim 1,
wherein each of said retrieving step and said adjusting step is performed on either hardware or software.

4. The method of claim 1,
wherein each of said plurality of output-gradation numbers corresponds to each of 8-bit, 10-bit, 12-bit, 14-bit and 16-bit.

5. A method for processing digital image data to be stored in a storage medium, said digital image data being created by applying a predetermined image-processing to original image data, which are read and converted from a visible pigment image through an image-inputting device after developing said visible pigment image on a silver-halide photosensitive material processed by an image-wise exposing operation, said method comprising the steps of:
designating a pixel number of said digital image data to be stored in said storage medium;
retrieving a gradation-setting data set, corresponding to said pixel number designated in said designating step, from a plurality of gradation-setting data sets, each of which corresponds to each of a plurality of pixel numbers established in advance; and
adjusting a gradation characteristic of said digital image data, based on said gradation-setting data set retrieved in said retrieving step.

6. The method of claim 5,
wherein said pixel number is designated by a user through an interface of a terminal processing device.

7. The method of claim 5,
wherein each of said retrieving step and said adjusting step is performed on either hardware or software.

8. The method of claim 5,
wherein each of said plurality of pixel numbers corresponds to each of image sizes having resolutions of 300 dpi, 600 dpi and 1200 dpi.

9. A method for processing digital image data to be stored in a storage medium, said digital image data being created by applying a predetermined image-processing to original image data, which are read and converted from a visible pigment image through an image-inputting device after developing said visible pigment image on a silver-halide photosensitive material processed by an image-wise exposing operation, said method comprising the steps of:
designating a combination of an output-gradation number and a pixel number of said digital image data to be stored in said storage medium;
retrieving a gradation-setting data set, corresponding to said combination of said output-gradation number and said pixel number designated in said designating step, from a plurality of gradation-setting data sets, each of which corresponds to each of combinations of output-gradation numbers and pixel numbers, said combinations being established in advance; and
adjusting a gradation of said digital image data, based on said gradation-setting data set retrieved in said retrieving step.

10. The method of claim 9,
wherein said combination of said output-gradation number and said pixel number is designated by a user through an interface of a terminal processing device.

11. The method of claim 9,
wherein each of said retrieving step and said adjusting step is performed on either hardware or software.

12. The method of claim 9,
wherein said output-gradation number corresponds to 8-bit, 10-bit, 12-bit, 14-bit or 16-bit, and said pixel number corresponds to an image size having a resolution of 300 dpi, 600 dpi or 1200 dpi.

13. A method for processing digital image data to be stored in a storage medium, said digital image data being created by applying a predetermined image-processing to original image data, which are read and converted from a visible pigment image through an image-inputting device after developing said visible pigment image on a silver-halide photosensitive material processed by an image-wise exposing operation, said method comprising the steps of:
storing both said digital image data and said original image data in said storage medium;
extracting necessary information from said original image data stored in said storage medium; and
applying an image-processing operation, for increasing and/or changing information content of said digital image data on the basis of said necessary information extracted from said original image data, to said digital image data read from said storage medium.

14. The method of claim 13,
wherein, in said storing step, an attached file, in which at least one of contents of said predetermined image-processing applied to said original image data and information for correlating said digital image data with said original image data is/are included, is also stored in said storage medium.

15. The method of claim 13,
wherein first gradation number “A” of said digital image data and second gradation number “B” of said original image data always fulfill the following first formula.
A<B

16. The method of claim 13,
wherein first pixel number “C” of said digital image data and second pixel number “D” of said original image data always fulfill the following second formula.
C<D

17. The method of claim 13,
wherein said predetermined image-processing and said image-processing applied in said applying step are an operation for compensating for gradation characteristics, and said necessary information are gradation information pertaining to said gradation characteristics.

18. The method of claim 13,
wherein said applying step is performed under an operating program of an attached application software stored in said storage medium.

19. A method for processing digital image data to be stored in a storage medium, said digital image data being created by applying a predetermined image-processing to original image data, which are read and converted from a visible pigment image through an image-inputting device after developing said visible pigment image on a silver-halide photosensitive material processed by an image-wise exposing operation, said method comprising the steps of:
storing both said digital image data and said original image data in said storage medium;
creating differential-component data between said digital image data and said original image data, both stored in said storage medium;
extracting necessary information from said differential-component data created in said creating step; and
applying an image-processing operation, for increasing and/or changing information content of said digital image data on the basis of said necessary information extracted from said original image data, to said digital image data read from said storage medium.

20. The method of claim 19,
wherein, in said storing step, an attached file, in which at least one of contents of said predetermined image-processing applied to said original image data and information for correlating said digital image data with said differential-component data is/are included, is also stored in said storage medium.

21. The method of claim 19,
wherein said predetermined image-processing and said image-processing applied in said applying step are an operation for compensating for gradation characteristics, and said necessary information are gradation information pertaining to said gradation characteristics.

22. The method of claim 19,
wherein said applying step is performed under an operating program of an attached application software stored in said storage medium.

23. A method for processing digital image data to be stored in a storage medium, said digital image data being created by applying a first predetermined image-processing to original image data, which are read and converted from a visible pigment image through an image-inputting device after developing said visible pigment image on a silver-halide photosensitive material processed by an image-wise exposing operation, said method comprising the steps of:
storing both said digital image data and sub-original image data in said storage medium, said sub-original image data being created by applying a second predetermined image-processing to said original image data;
extracting necessary information from said sub-original image data stored in said storage medium; and
applying an image-processing operation, for increasing and/or changing information content of said digital image data on the basis of said necessary information extracted from said original image data, to said digital image data read from said storage medium.

24. The method of claim 23,
wherein, in said storing step, an attached file, in which at least one of contents of said first predetermined image-processing applied to said original image data, contents of said second predetermined image-processing applied to said original image data and information for correlating said digital image data with said original image data is/are included, is also stored in said storage medium.

25. The method of claim 23,
wherein first gradation number “A” of said digital image data and second gradation number “E” of said sub-original image data always fulfill the following third formula.
A<E

26. The method of claim 23,
wherein first pixel number “C” of said digital image data and second pixel number “F” of said sub-original image data always fulfill the following fourth formula.
C<F

27. The method of claim 23,
wherein said first predetermined image-processing, said second predetermined image-processing and said image-processing applied in said applying step are an operation for compensating for gradation characteristics, and said necessary information are gradation information pertaining to said gradation characteristics.

28. The method of claim 23,
wherein said applying step is performed under an operating program of an attached application software stored in said storage medium.
